(19) United States
(12) Patent Application Publication
(10) Pub. No.: US 2025/0192035 A1
(43) Pub. Date: Jun. 12, 2025

(54) SEMICONDUCTOR CHIP WITH DUAL CHIP-PAD STRUCTURE AND SEMICONDUCTOR PACKAGE INCLUDING SEMICONDUCTOR CHIP

(71) Applicant: Samsung Electronics Co., Ltd., Suwon-si (KR)

(72) Inventors: Keunyoung LEE, Suwon-si (KR); Sangsub Song, Suwon-si (KR); Kihong Jeong, Suwon-si (KR)

(73) Assignee: SAMSUNG ELECTRONICS CO., LTD., Suwon-si (KR)

(21) Appl. No.: 18/767,417

(22) Filed: Jul. 9, 2024

(30) Foreign Application Priority Data
Dec. 12, 2023 (KR) 10-2023-0180104

(51) Int. Cl. H01L 23/528; H01L 23/00; H01L 25/18

(52) U.S. Cl. CPC H01L 23/528; H01L 24/06; H01L 24/08; H01L 24/32; H01L 24/48; H01L 24/73; H01L 25/18; H01L 2224/06137; H01L 2224/06515; H01L 2224/08225; H01L 2224/32145; H01L 2224/32225; H01L 2224/48137; H01L 2224/48147; H01L 2224/48227; H01L 2224/73265; H01L 2225/06506; H01L 2225/0651; H01L 2225/06562; H01L 2924/1815

(57) ABSTRACT

A semiconductor chip with a dual chip-pad structure includes a chip body, a first chip-pad disposed on a first edge of a top surface of the chip body and a second edge of the top surface of the chip body, and a second chip-pad disposed along the second direction at a central portion of the top surface between the first edge of the top surface of the chip body and the second edge of the top surface of the chip body in the first direction. The second edge of the top surface is opposite to the first edge of the top surface in a first direction. The first chip-pad is disposed along a second direction perpendicular to the first direction. The first chip-pad includes a first signal pad coupled with the second chip-pad.

### CROSS-REFERENCE TO RELATED APPLICATIONS

This application claims benefit of priority under 35 U.S.C. § 119 to Korean Patent Application No. 10-2023-0180104, filed on Dec. 12, 2023, in the Korean Intellectual Property Office, the disclosure of which is incorporated by reference herein in its entirety.

### BACKGROUND

### 1. Field

The present disclosure relates generally to a semiconductor chip, and more particularly, to a semiconductor chip with a dual chip-pad structure and a semiconductor package including the semiconductor chip.

### 2. Description of Related Art

Electronic devices may become smaller and/or lighter due to developments of the electronics industry and/or due to increasing demands from users of the electronic devices. As electronic devices potentially become smaller and/or lighter, semiconductor packages used therein may also need to become smaller and/or lighter. Additionally, the semiconductor packages may need to have relatively high reliability, relatively high and/or improved performance, and/or relatively large and/or improved capacity. Consequently, signal transmission paths to the semiconductor packages may become more complex in order to potentially meet the reliability, performance, and/or capacity requirements imposed on the semiconductor packages. Accordingly, the importance of a structure of a semiconductor package that may correspond to the size and/or performance of the semiconductor package and stably transmit signals to the semiconductor package may be increasing.

### SUMMARY

One or more example embodiments of the present disclosure provide a semiconductor chip that has an efficient chip-pad arrangement structure and may reduce the size of a semiconductor package, and a semiconductor package including the semiconductor chip.

According to an aspect of the present disclosure, a semiconductor chip with a dual chip-pad structure includes a chip body, a first chip-pad disposed on a first edge of a top surface of the chip body and a second edge of the top surface of the chip body, and a second chip-pad disposed along the second direction at a central portion of the top surface between the first edge of the top surface of the chip body and the second edge of the top surface of the chip body in the first direction. The second edge of the top surface being opposite to the first edge of the top surface in a first direction. The first chip-pad being disposed along a second direction perpendicular to the first direction. The first chip-pad includes a first signal pad coupled with the second chip-pad.

According to an aspect of the present disclosure, a semiconductor package includes a package substrate, a first semiconductor chip disposed on the package substrate, having a first dual chip-pad structure, and including a chip body, a first chip-pad, and a second chip-pad disposed on a top surface of the chip body, and a first chip stacked structure disposed on the package substrate adjacent to the first semiconductor chip in a first direction and including a first plurality of memory chips stacked therein. The first chip-pad is disposed on a first edge of the top surface of the chip body and a second edge of the top surface of the chip body. The second edge of the top surface being opposite to the first edge of the top surface in the first direction. The first chip-pad being disposed along a second direction perpendicular to the first direction. The second chip-pad is disposed along the second direction at a central portion of the top surface between the first edge of the top surface of the chip body and the second edge of the top surface of the chip body in the first direction. The first chip-pad includes a first signal pad coupled with the second chip-pad.

According to an aspect of the present disclosure, a semiconductor package includes a package substrate, a first semiconductor chip on the package substrate, having a first dual chip-pad structure, and including a chip body, a first chip-pad, and a second chip-pad disposed on a top surface of the chip body, a second semiconductor chip on the package substrate adjacent to the first semiconductor chip in a first direction and having a second dual chip-pad structure same as the first dual chip-pad structure of the first semiconductor chip, and a chip stacked structure disposed on the first semiconductor chip and the second semiconductor chip and including a plurality of memory chips stacked therein. The first chip-pad of each of the first semiconductor chip and the second semiconductor chip is disposed on a first edge of the top surface of the chip body and a second edge of the top surface of the chip body. The second edge of the top surface being opposite to the first edge of the top surface in the first direction. The first chip-pad being disposed along a second direction perpendicular to the first direction. The second chip-pad of each of the first semiconductor chip and the second semiconductor chip is disposed along the second direction at a central portion of the top surface between the first edge of the top surface of the chip body and the second edge of the top surface of the chip body in the first direction. The first chip-pad of each of the first semiconductor chip and the second semiconductor chip includes a first signal pad coupled with the second chip-pad.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a plan view schematically illustrating a semiconductor chip, according to an embodiment;

FIG. 2A is a plan view illustrating a semiconductor chip, according to a comparative example;

FIGS. 2B and 2C are perspective views illustrating structures in which the semiconductor chip of FIG. 1 and the semiconductor chip of FIG. 2A are connected to a package substrate through a wire, according to embodiments;

FIGS. 3A, 3B, and 4A to 4C are conceptual views illustrating a connection relationship between a second chip-pad and a first signal pad of a first chip-pad in the semiconductor chip of FIG. 1, according to embodiments;

FIGS. 5A and 5B are cross-sectional views illustrating a semiconductor package including the semiconductor chip of FIG. 1, according to embodiments;

FIGS. 6A and 6B are cross-sectional views illustrating a semiconductor package including the semiconductor chip of FIG. 1, according to embodiments;

FIGS. 7A and 7B are cross-sectional views illustrating a semiconductor package including the semiconductor chip of FIG. 1, according to embodiments;

FIG. 8 is a cross-sectional view illustrating a semiconductor package including the semiconductor chip of FIG. 1, according to an embodiment; and

FIGS. 9A and 9B are cross-sectional views illustrating a semiconductor package including the semiconductor chip, according to embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any of possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” “third” to be used to describe relative positions of elements. The terms “first,” “second,” “third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “GaAs”, “InAs”, “InP”, “SiC”, “SiGe”, and the like may refer to a material made of elements included in each of the terms and is not a chemical formula representing a stoichiometric relationship.

Hereinafter, various embodiments of the present disclosure are described with reference to the accompanying drawings.

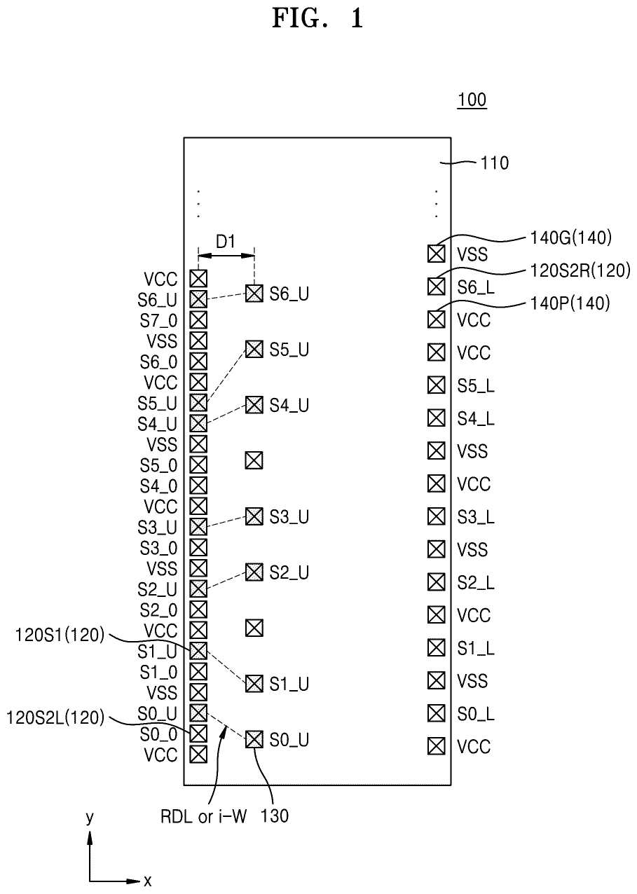

FIG. 1 is a plan view schematically illustrating a semiconductor chip, according to an embodiment.

Referring to FIG. 1, a semiconductor chip 100 of the present disclosure may include a chip body 110, a first chip-pad 120, a second chip-pad 130, and a third chip-pad 140.

The chip body 110 may form a body of the semiconductor chip 100. A top surface of the chip body 110 may have a rectangular shape with a long side in one direction. However, a shape of the chip body 110 is not limited thereto. For example, according to an embodiment, the top surface of the chip body 110 may have a shape similar to a square shape.

The chip body 110 may include a substrate and an active layer. The substrate may include, but not be limited to, silicon (Si). For example, the silicon (Si) may be in the form of single crystalline Si, polycrystalline Si (poly Si), amorphous Si, or the like. However, a material of the substrate is not limited to silicon. For example, in some embodiments, the substrate may include a group IV semiconductor (e.g., germanium (Ge)), a group IV-IV compound semiconductor (e.g., silicon germanium (SiGe) or silicon carbide (SiC)), or a group III-V compound semiconductor (e.g., gallium arsenide (GaAs), indium arsenide (InAs), or indium phosphide (InP)).

In an embodiment, the substrate may be based on a silicon (Si) bulk substrate. Alternatively or additionally, the substrate may be based on a silicon-on-insulator (SOI) substrate or a germanium-on-insulator (GeOI) substrate. However, the present disclosure is not limited in this regard, and the substrate may be based on an epitaxial wafer, a polished wafer, an annealed wafer, or the like.

The active layer may be and/or may include an integrated circuit layer and a multi-wiring layer. The integrated circuit layer may be formed by using an impurity region of an upper portion of the substrate. For example, the integrated circuit layer may be and/or may include transistors including a gate electrode and an impurity region such as a source/drain region. However, elements included in the integrated circuit layer are not limited to transistors. The multi-wiring layer may be located on the integrated circuit layer and may include internal wirings of multiple layers. The internal wirings may be electrically connected to the integrated circuit layer through contacts. Alternatively or additionally, the internal wirings of different layers in the multi-wiring layer may be connected to each other through vertical vias.

A top surface of the active layer may correspond to an active surface, and a bottom surface of the substrate opposite to the active surface may correspond to an inactive surface. In and embodiment, the first to third chip-pads 120 to 140 may be located on the top surface of the active layer. A quadrangular surface shown in FIG. 1 may correspond to the top surface of the chip body 110 and may correspond to the top surface of the active layer. In an embodiment, a passivation layer such as, but not limited to, an oxide film, a nitride film, or an oxynitride film, may be located on the top surface of the active layer to protect the semiconductor chip 100.

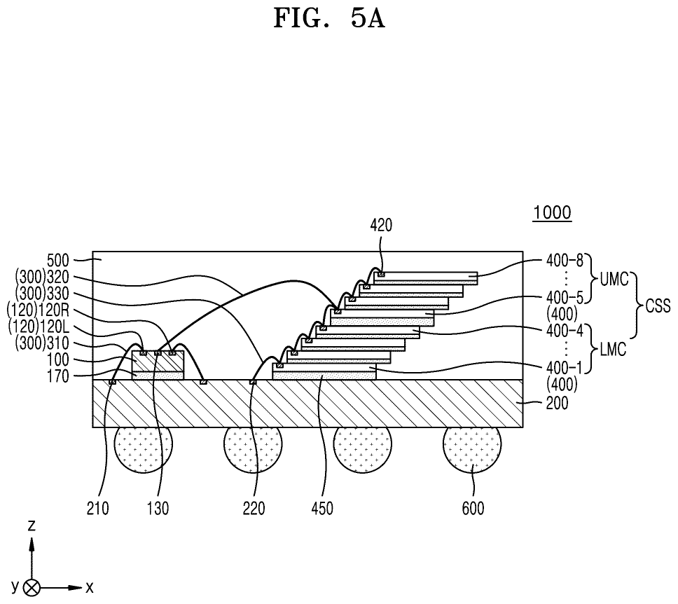

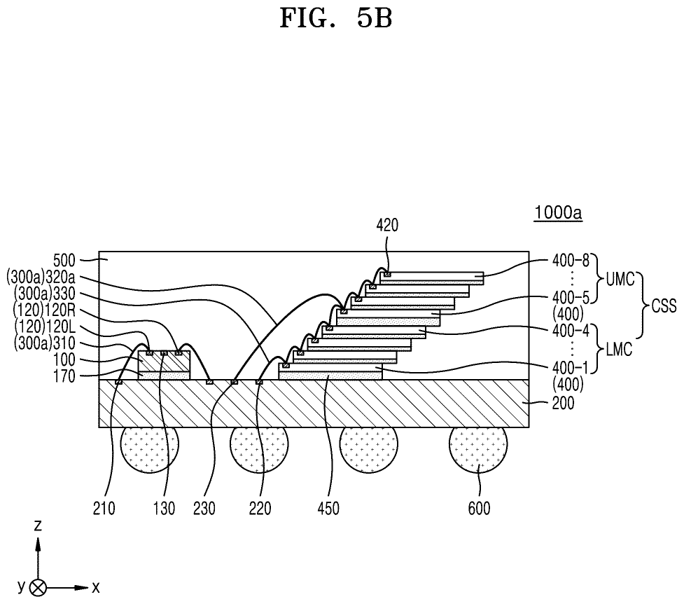

The semiconductor chip 100 of the present disclosure may be and/or may include, for example, a buffer chip, and may include logic elements therein. In an embodiment, the buffer chip may be located on a package substrate together with a chip stacked structure to constitute a semiconductor package. The buffer chip may integrate signals of memory chips of the chip stacked structure and may transmit the signals to the outside, and may also transmit signals and power from the outside to the memory chips. According to embodiments, the buffer chip may be referred to as a control chip. The buffer chip is further described with reference to FIG. 5A.

The first chip-pad 120 may be located on an edge of the top surface of the chip body 110. For example, when the top surface of the chip body 110 has a rectangular shape that is long in a y direction, the first chip-pad 120 may be located along the y direction on both edges in an x direction (e.g., a first edge and a second edge).

The first chip-pad 120 may include a plurality of signal pads. The plurality of signal pads may refer to pads for transmitting signals such as, but not limited to, read, write, and erase signals to the memory chips of the chip stacked structure. As shown in FIG. 1, pads with names starting with “S” may correspond to signal pads.

The first chip-pad 120 may include a first signal pad 120S1 and second signal pads (e.g., a right second signal pad 120S2R and a left second signal pad 120S2L). The first signal pad 120S1 may be located along the y direction on a left edge in the x direction. In some embodiments, the first signal pad 120S1 may be located along the y direction on a right edge in the x direction. The left second signal pad 120S2L from among the second signal pads 120S2R and 120S2L may be located along the y direction on a left edge in the x direction. The right second signal pad 120S2R from among the second signal pads 120S2R and 120S2L may be located along the y direction on a right edge in the x direction.

As shown in FIG. 1, the first signal pad 120S1 may correspond to pads with names ending with “_U”, and may be connected to upper memory chips of the chip stacked structure. In addition, the right second signal pads 120S2R may correspond to pads with names ending with “_L”, and may be connected to lower memory chips of the chip stacked structure. Continuing to refer to FIG. 1, the left second signal pads 120S2L may correspond to pads with names ending with “_0”.

The second chip-pad 130 may be located along the y direction at a central portion between both edges on the top surface of the chip body 110 in the x direction. The second chip-pad 130 may be located at a central portion on the top surface of the chip body 110 while being biased toward any one edge in the x direction (e.g., a left edge). However, according to embodiments, the second chip-pad 130 may be located at a central portion on the top surface of the chip body 110 while being biased toward a right side in the x direction, or may be located at the exact center on the top surface of the chip body 110 in the x direction. In the x direction, a first distance D1 between the first chip-pad 120 and the second chip-pad 130 may be maintained. The first distance D1 may be, for example, 75 micrometers (μm) or more. However, the first distance D1 is not limited to the numerical range.

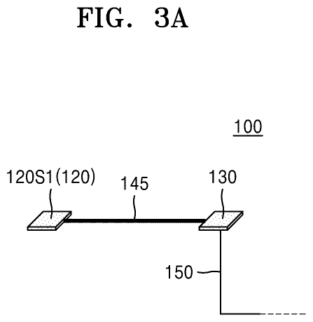

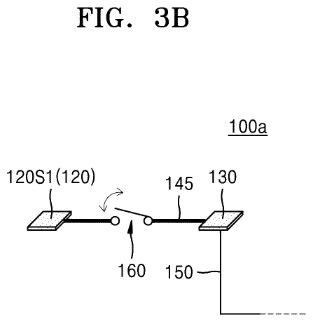

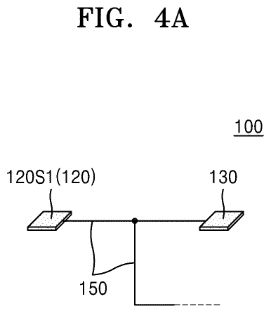

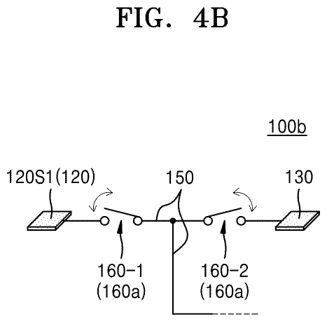

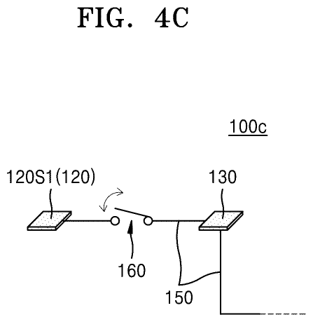

The second chip-pad 130 may include a plurality of signal pads. The second chip-pad 130 may be connected to the upper memory chips of the chip stacked structure. As shown in FIG. 1, the second chip-pad 130 may also be connected to the upper memory chips, and thus, may have names ending with “_U”. In addition, as marked by a dashed line in FIG. 1, the second chip-pad 130 may be electrically connected to the first signal pad 120S1 of the first chip-pad 120. The connection between the second chip-pad 130 and the first signal pad 120S1 may be implemented through an internal wiring i-W of the multi-wiring layer or a redistribution layer (RDL). A connection structure between the second chip-pad 130 and the first signal pad 120S1 is further described with reference to FIGS. 3A to 4C.

When the second chip-pad 130 and the first signal pad 120S1 are connected to each other, it may indicate that the second chip-pad 130 and the first signal pad 120S1 transmit a substantially similar and/or the same signal. Accordingly, the memory chips that may be connected to the second chip-pad 130 and the first signal pad 120S1 may be the same. As further described with reference to FIG. 5A, the second chip-pad 130 and the first signal pad 120S1 of the semiconductor chip 100 may correspond to chip-pads having a substantially similar and/or the same function and may be selectively used when used in a semiconductor package. That is, when the second chip-pad 130 is used, the first signal pad 120S1 may not be used. Alternatively or additionally, when the first signal pad 120S1 is used, the second chip-pad 130 may not be used. When a chip-pad is used, it may indicate that the chip-pad is connected to a wire in a connection structure through wire bonding, and when a chip-pad is not used, it may indicate that the chip-pad is not connected to a wire. Because the second chip-pad 130 and the first signal pad 120S1 may have the same function, the semiconductor chip 100 of the present disclosure may have a dual chip-pad structure.

In some embodiments, a chip-pad that is not used from among the second chip-pad 130 and the first signal pad 120S1 may be deactivated. Deactivation of the second chip-pad 130 and the first signal pad 120S1 is further described with reference to FIGS. 3A to 4C.

The third chip-pad 140 may be located along the y direction on both edges on the top surface of the chip body 110. That is, the third chip-pad 140 may be located along the y direction on each of a right edge and a left edge on the top surface of the chip body 110 in the x direction. The third chip-pad 140 may include a power supply pad 140P and a ground pad 140G. The power supply pad 140P may provide power to the memory chips of the chip stacked structure, and the ground pad 140G may provide a ground to the memory chips of the chip stacked structure. In FIG. 1, pads named VCC may correspond to the power supply pads 140P, and pads named VSS may correspond to the ground pads 140G.

The semiconductor chip 100 of the present disclosure may include the first chip-pad 120 located on both sides and the second chip-pad 130 located at a central portion between the both edges, and the first chip-pad 120 may include the first signal pad 120S1 electrically connected to the second chip-pad 130. In an embodiment, such a chip-pad arrangement structure of the semiconductor chip 100 of the present disclosure that may be used as a buffer chip of a semiconductor package, may allow for implementation of an efficient wire bonding structure with memory chips of a chip stacked structure of the semiconductor package. Accordingly, the chip-pad arrangement structure may significantly reduce the overall size of the semiconductor package.

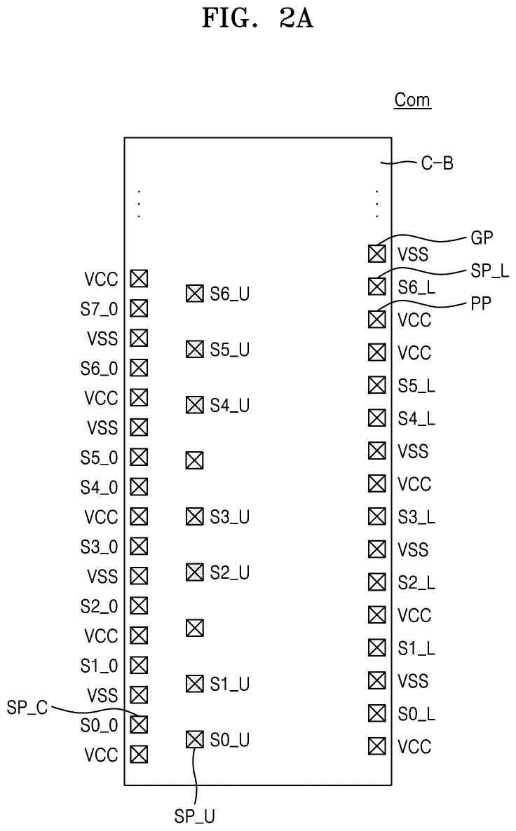

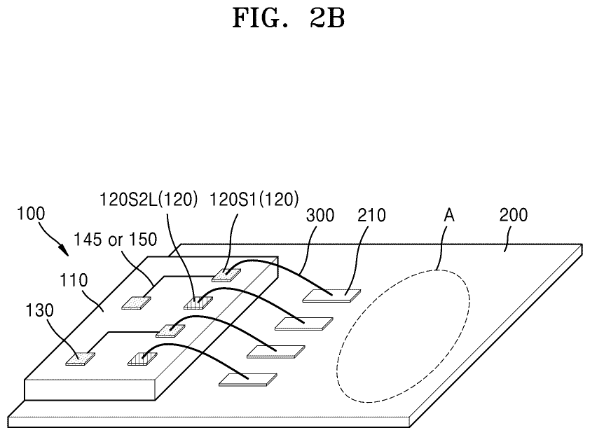

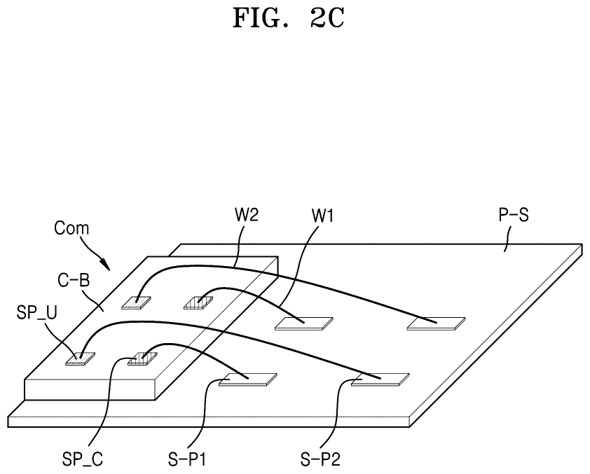

FIG. 2A is a plan view illustrating a semiconductor chip, according to a comparative example. FIG. 2B is a perspective view illustrating a structure in which the semiconductor chip of FIG. 1 is connected to a package substrate through a wire, according to an embodiment. FIG. 2C is a perspective view illustrating a structure in which the semiconductor chip of FIG. 2A is connected to a package substrate through a wire, according to an embodiment.

Referring to FIG. 2A, a semiconductor chip Com may include chip-pads located on a top surface of a chip body C-B. The chip-pads may include signal pads (e.g., a lower signal pad SP_L, a common signal pad SP_C, and an upper signal pad SP_U), power supply pads PP and ground pads GP. The lower signal pad SP_L and the common signal pad SP_C may be located on edges of the top surface of the chip body C-B. Alternatively or additionally, the upper signal pad SP_U may be located at a central portion on the top surface of the chip body C-B. As shown in FIG. 2A, the semiconductor chip Com may be used as a buffer chip of a semiconductor package, and when connected to memory chips of a chip stacked structure, the lower signal pad SP_L may be connected to lower memory chips of the chip stacked structure and the upper signal pad SP_U may be connected to the upper memory chips of the chip stacked structure. In the semiconductor chip Com, there may be no signal pad connected to the upper signal pad SP_U on the edge of the top surface of the chip body C-B.

Referring to FIGS. 2B and 2C, in the semiconductor chip 100 of the present disclosure, the second chip-pad 130 may be connected to the first signal pad 120S1 of the first chip-pad 120 located on an edge through an RDL 145 and/or an internal wiring 150. Accordingly, without having to directly connect the second chip-pad 130 to a substrate pad 210 of a package substrate 200, the second chip-pad 130 may be indirectly connected to the substrate pad 210 of the package substrate 200 by using the first signal pad 120S1 and a wire 300.

Alternatively in the semiconductor chip Com as shown in FIG. 2C, a signal pad corresponding to the upper signal pad SP_U is not located on an edge. Accordingly, the common signal pad SP_C located on an edge may be connected to a first substrate pad S-P1 of a package substrate P-S located close (e.g., near, within a certain threshold) to the semiconductor chip Com through a first wire W1. Alternatively, the upper signal pad SP_U at a central portion may be connected to a second substrate pad S-P2 of the package substrate P-S located far from the semiconductor chip Com through a second wire W2.

That is, compared to a case where the semiconductor chip 100 of the present disclosure is used as a buffer chip of a semiconductor package, when the semiconductor chip Com is used as a buffer chip of a semiconductor package, the size of the package substrate 200 may increase by a portion where the second substrate pad S-P2 is located, that is, a portion A marked by a dashed line in FIG. 2B, and the overall size of the semiconductor package may also increase correspondingly. In addition, the use of a relatively long second wire W2 may result in a potential waste of wire materials and/or problems of wire connection reliability and signal reliability deterioration.

However, because the semiconductor chip 100 of the present disclosure includes the first chip-pad 120 located on both edges and the second chip-pad 130 located at a central portion between the both edges, and the first chip-pad 120 includes the first signal pad 120S1 electrically connected to the second chip-pad 130, potential problems of the semiconductor chip Com may be prevented.

FIGS. 3A to 4C are conceptual views illustrating a connection relationship between a second chip-pad and a first signal pad of a first chip-pad in the semiconductor chip of FIG. 1, according to an embodiment. The semiconductor chips 100, 100a, 100b, and 100c of FIGS. 3A to 4C may include and/or may be similar in many respects to the semiconductor chip 100 described above with reference to FIGS. 1 to 2C, and may include additional features not mentioned above. Consequently, repeated descriptions of the semiconductor chips 100, 100a, 100b, and 100c described above with reference to FIGS. 1 to 2C may be omitted for the sake of brevity.

Referring to FIG. 3A, in the semiconductor chip 100 of the present disclosure, the second chip-pad 130 and the first signal pad 120S1 of the first chip-pad 120 may be connected to each other through the RDL 145. Alternatively or additionally, the second chip-pad 130 may be connected to the internal wiring 150 of the multi-wiring layer of the chip body 110. In the semiconductor chip 100 of the present disclosure, regardless of whether the second chip-pad 130 and the first signal pad 120S1 are used, both may be maintained in an active state.

Referring to FIG. 3B, in a semiconductor chip 100a of the present disclosure, the second chip-pad 130 and the first signal pad 120S1 of the first chip-pad 120 may be connected to each other through the RDL 145. Alternatively or additionally, the second chip-pad 130 may be connected to the internal wiring 150 of the multi-wiring layer of the chip body 110. The semiconductor chip 100a of the present disclosure may further include a switching element 160 located on the RDL 145. The switching element 160 may include, for example, a transistor. However, a type of the switching element 160 is not limited to a transistor.

In the semiconductor chip 100a of the present disclosure, when the first signal pad 120S1 is not used, the first signal pad 120S1 may be deactivated through the switching element 160. That is, when a wire is not connected to the first signal pad 120S1, the first signal pad 120S1 may be disconnected from the second chip-pad 130 by turning off the switching element 160. As such, because the first signal pad 120S1 that is not used is deactivated, a short circuit with another first chip-pad 120 or a wire adjacent to the first signal pad 120S1 may be prevented.

Although the internal wiring 150 is depicted as being directly connected to the second chip-pad 130 in FIG. 3B, the present disclosure is not limited thereto. For example, the internal wiring 150 may be directly connected to the first signal pad 120S1. In such an example, when the second chip-pad 130 is not used, the second chip-pad 130 may be deactivated through the switching element 160.

Referring to FIG. 4A, in the semiconductor chip 100 of the present disclosure, the second chip-pad 130 and the first signal pad 120S1 of the first chip-pad 120 may be connected to each other through the internal wiring 150 of the multi-wiring layer. In the semiconductor chip 100 of the present disclosure, regardless of whether the second chip-pad 130 and the first signal pad 120S1 are used, both may be maintained in an active state. Although two internal wirings 150 are depicted as branching from one internal wiring 150 and being connected to the second chip-pad 130 and the first signal pad 120S1 in FIG. 4A, the present disclosure is not limited thereto. For example, the internal wiring 150 may be connected to any one of the second chip-pad 130 and the first signal pad 120S1 and the second chip-pad 130 and the first signal pad 120S1 may be connected to each other through another internal wiring 150.

Referring to FIG. 4B, in a semiconductor chip 100b of the present disclosure, the second chip-pad 130 and the first signal pad 120S1 of the first chip-pad 120 may be connected to each other through the internal wiring 150 of the multi-wiring layer. Alternatively or additionally, the semiconductor chip 100b of the present disclosure may further include a switching element 160a located on the internal wiring 150. The switching element 160a may include a first switching element 160-1 located close (e.g., near, within a threshold) to the first signal pad 120S1 and a second switching element 160-2 located close to the second chip-pad 130. The switching element 160a may include, for example, a transistor. However, a type of the switching element 160a is not limited to a transistor.

In the semiconductor chip 100b of the present disclosure, a chip-pad that is not used from among the second chip-pad 130 and the first signal pad 120S1 may be deactivated through the switching element 160a. That is, a chip-pad that is not connected to a wire may be electrically turned off by turning off the switching element 160a. As such, because a chip-pad that is not used is deactivated, a short circuit with another chip-pad or a wire adjacent to the chip-pad may be prevented.

Referring to FIG. 4C, in a semiconductor chip 100c of the present disclosure, the second chip-pad 130 and the first signal pad 120S1 of the first chip-pad 120 may be connected to each other through the internal wiring 150 of the multi-wiring layer. Alternatively or additionally, the second chip-pad 130 may be connected to the internal wiring 150 of the multi-wiring layer of the chip body 110. The semiconductor chip 100c of the present disclosure may further include the switching element 160 located on the internal wiring 150 between the second chip-pad 130 and the first signal pad 120S1. The switching element 160 may include, for example, a transistor. However, a type of the switching element 160 is not limited to a transistor.

In the semiconductor chip 100c of the present disclosure, when the first signal pad 120S1 is not used, the first signal pad 120S1 may be deactivated through the switching element 160. That is, when a wire is not connected to the first signal pad 120S1, the first signal pad 120S1 may be disconnected from the second chip-pad 130 by turning off the switching element 160. As such, because the first signal pad 120S1 that is not used is deactivated, a short circuit with another first chip-pad 120 or a wire adjacent to the first signal pad 120S1 may be prevented.

Although the internal wiring 150 is depicted as being directly connected to the second chip-pad 130 in FIG. 4C, the present disclosure is not limited thereto and the internal wiring 150 may be directly connected to the first signal pad 120S1. In such an embodiment, when the second chip-pad 130 is not used, the second chip-pad 130 may be deactivated through the switching element 160.

FIGS. 5A and 5B are cross-sectional views illustrating a semiconductor package including the semiconductor chip of FIG. 1, according to embodiments. FIGS. 5A and 5B are described together with FIG. 1. Repeated descriptions of elements described with reference to FIGS. 1 to 4C may be omitted for the sake of brevity.

Referring to FIG. 5A, a semiconductor package 1000 of the present disclosure may include the semiconductor chip 100, the package substrate 200, the wire 300, the chip stacked structure CSS, a sealing member 500, and an external connection terminal 600.

The semiconductor chip 100 may be and/or may include the semiconductor chip 100 of FIG. 1. Thus, repeated descriptions of elements described with reference to FIG. 1 may be omitted for the sake of brevity. As shown in FIG. 5A, in the semiconductor package 1000 of the present disclosure, the semiconductor chip 100 may be stacked on the package substrate 200 through an adhesive layer 170. The adhesive layer 170 may be and/or may include, for example, a die attach film (DAF). However, the adhesive layer 170 is not limited to a DAF. A connection relationship of the semiconductor chip 100 through the wire 300 is described when the chip stacked structure CSS is described.

The package substrate 200 may be located under the semiconductor chip 100 and the chip stacked structure CSS and may support the semiconductor chip 100 and the chip stacked structure CSS. In the semiconductor package 1000 of the present disclosure, the package substrate 200 may be and/or may include, for example, a printed circuit board (PCB). However, the package substrate 200 is not limited to a PCB.

The package substrate 200 may include a substrate body, a substrate wiring layer, and a protective layer. The substrate body may include a glass fiber and a resin such as FR4. However, a material of the substrate body is not limited thereto. For example, the substrate body may include a bismaleimide-triazine (BT) resin, a poly carbonate (PC) resin, a build-up film (e.g., an Ajinomoto Build-Up Film® (ABF)), or another laminate resin.

The substrate wiring layer may be located in the substrate body. For example, the substrate wiring layer may include substrate wirings in an 8 to 20-layer structure. However, the number of layers of substrate wirings is not limited to the above range. Substrate wirings of different layers may be connected to each other through vertical vias. The protective layer may be and/or may include a layer for protecting the substrate body and the substrate wiring layer from external physical and chemical damage. The protective layer may include an upper protective layer and a lower protective layer. The protective layer may include, for example, a solder resist (SR). However, a material of the protective layer is not limited to an SR.

As shown in FIG. 5A, the chip stacked structure CSS may include a plurality of memory chips 400 stacked in a vertical direction (e.g., in a z direction) on the package substrate 200. In the semiconductor package 1000 of the present disclosure, each of the memory chips 400 of the chip stacked structure CSS may be and/or may include a flash memory chip (e.g., a NAND flash memory chip). However, a type of the memory chip 400 is not limited to a flash memory chip.

As shown in FIG. 5A, in the chip stacked structure CSS, the memory chips 400 may be stacked in a stepwise structure. For example, the chip stacked structure CSS may have a stepwise structure in which positions of the memory chips 400 increase upward and to a right side in the x direction. In the semiconductor package 1000 of the present disclosure, the chip stacked structure CSS may include eight (8) memory chips 400, as an example. However, the number of memory chips 400 included in the chip stacked structure CSS is not limited to eight (8). In the chip stacked structure CSS, the eight (8) memory chips 400 may be divided into lower memory chips LMC including four (4) memory chips 400 located at a lower position and upper memory chips UMC including four (4) memory chips 400 located at a higher position. For example, the lower memory chips LMC may exchange signals through a lower channel, and the upper memory chips UMC may exchange signals through an upper channel.

Each of the memory chips 400 may be stacked on the package substrate 200 or the lower memory chip 400 through an adhesive layer 450. The adhesive layer 450 may be, for example, a DAF. However, a material of the adhesive layer 450 is not limited to a DAF. A lowermost first memory chip 400-1 from among the lower memory chips LMC and a lowermost fifth memory chip 400-5 from among the upper memory chips UMC may be stacked through an adhesive layer 450 that may be thicker than other memory chips 400. However, in some embodiments, the adhesive layers 450 may all have a substantially similar and/or the same thickness.

A connection relationship through the wire 300 between the semiconductor chip 100, the memory chips 400 of the chip stacked structure CSS, and the package substrate 200 may be implemented as follows.

The semiconductor chip 100 may be connected to a first substrate pad 210 of the package substrate 200 through a first wire 310. That is, a right chip-pad 120R located on a right edge of the semiconductor chip 100 in the x direction may be connected to the first substrate pad 210 on a right side of the semiconductor chip 100 in the x direction through the first wire 310. Alternatively or additionally, a left chip-pad 120L located on a left edge of the semiconductor chip 100 in the x direction may be connected to the first substrate pad 210 on a left side of the semiconductor chip 100 in the x direction through the first wire 310. As shown in FIG. 1, the right chip-pad 120R and the left chip-pad 120L may include the first chip-pad 120 and the third chip-pad 140. However, for convenience, in FIGS. 5A to 9B, only the first chip-pad 120 may be illustrated and the third chip-pad 140 may not be illustrated. The first chip-pad 120 of the right chip-pad 120R may include a right second signal pad 120S2R, and the first chip-pad 120 of the left chip-pad 120L may include the first signal pad 120S1 and a left second signal pad 120S2L.

The semiconductor chip 100 may be directly connected to the upper memory chips UMC of the chip stacked structure CSS through a second wire 320. That is, the second chip-pad 130 located at a central portion of the semiconductor chip 100 may be connected to a chip-pad 420 of the fifth memory chip 400-5 from among the upper memory chips UMC through the second wire 320. The chip stacked structure CSS may be connected to a second substrate pad 220 of the package substrate 200 through a third wire 330. That is, the chip-pad 420 of the first memory chip 400-1 of the chip stacked structure CSS may be connected to the second substrate pad 220 of the package substrate 200 through the third wire 330.

The right second signal pad 120S2R of the first chip-pad 120 of the semiconductor chip 100 may be and/or may include a lower channel pad, and may be connected to the chip-pad 420 of the lower memory chips LMC through the first wire 310, the first substrate pad 210, the second substrate pad 220, and the third wire 330 to exchange signals with the lower memory chips LMC. The first substrate pad 210 and the second substrate pad 220 may be connected to each other through the substrate wiring of the package substrate 200. However, in some embodiments, the first substrate pad 210 and the second substrate pad 220 may be integrated into one substrate pad, and in such embodiments, may be directly connected without the substrate wiring.

The second chip-pad 130 of the semiconductor chip 100 may be and/or may include an upper channel pad, and may be connected to the chip-pad 420 of the upper memory chips UMC through the second wire 320 to exchange signals with the upper memory chips UMC. As the second chip-pad 130 of the semiconductor chip 100 is used, the first signal pad 120S1 of the first chip-pad 120 may not be used. That is, a wire may not be connected to the first signal pad 120S1. Alternatively or additionally, according to various wiring connection structures of FIGS. 3A to 4C, the first signal pad 120S1 may be deactivated or maintained in an active state.

The left second signal pad 120S2L of the first chip-pad 120 of the semiconductor chip 100 may be and/or may include a common channel pad, and may be connected to the external connection terminal 600 of the package substrate 200 through the substrate wiring of the package substrate 200. Alternatively or additionally, the third chip-pad 140 of the semiconductor chip may also be connected to the chip-pad 420 of the memory chips 400 through the first wire 310, the first substrate pad 210, the second substrate pad 220, and the third wire 330 to provide power and/or a ground to the memory chips 400.

The sealing member 500 may cover and seal the semiconductor chip 100, the chip stacked structure CSS, and the wire 300 on the package substrate 200. The sealing member 500 may seal the semiconductor chip 100 and the memory chips 400 of the chip stacked structure CSS to protect the semiconductor chip 100 and the memory chips 400 from external physical and chemical damage. The sealing member 500 may include an insulating material, for example, but not limited to, a thermosetting resin (e.g., epoxy resin) or a thermoplastic resin (e.g., polyimide). Alternatively or additionally, the sealing member 500 may include a thermosetting resin or a thermoplastic resin containing a reinforcing material such as, but not limited to, an inorganic filler (e.g., ABF, flame retardant 4 (FR-4), or BT resin). Alternatively or additionally, the sealing member 500 may include, but not be limited to, a molding material such as epoxy molding compound (EMC) or a photosensitive material such as photo imageable encapsulant (PIE). In the semiconductor package 1000 of the present disclosure, the sealing member 500 may include, for example, EMC. However, a material of the sealing member 500 is not limited to the above materials.

The external connection terminal 600 may be located on a bottom surface of the package substrate 200. For example, the external connection terminal 600 may be located on an external pad on the bottom surface of the package substrate 200. The external connection terminal 600 may be electrically connected to the substrate wiring of the package substrate 200 through the external pad. The external connection terminal 600 may include a solder ball. However, according to embodiments, the external connection terminal 600 may include a pillar and a solder. The semiconductor package 1000 of the present disclosure may be mounted on an external substrate such as an imposer or a base substrate through the external connection terminal 600.

Referring to FIG. 5B, a semiconductor package 1000a of the present disclosure may differ from the semiconductor package 1000 of FIG. 5A in a connection structure of a wire 300a between the semiconductor chip 100 and the chip stacked structure CSS. That is, the semiconductor package 1000a of the present disclosure may include the semiconductor chip 100, the package substrate 200, the wire 300a, the chip stacked structure CSS, the sealing member 500, and the external connection terminal 600. The semiconductor chip 100, the package substrate 200, the chip stacked structure CSS, the sealing member 500, and the external connection terminal 600 may include and/or may be similar in many respects to those in the semiconductor package 1000 of FIG. 5A.

A connection relationship through the wire 300a between the semiconductor chip 100, the memory chips 400 of the chip stacked structure CSS, and the package substrate 200 may be described as follows.

A connection relationship through the wire 300a between the second signal pads 120S2R and 120S2L of the first chip-pad 120 and the third chip-pad 140 of the semiconductor chip 100 and the chip stacked structure CSS may be substantially similar and/or the same as that in the semiconductor package 1000 of FIG. 5A.

In the semiconductor package 1000a of the present disclosure, the first signal pad 120S1 of the first chip-pad 120 of the semiconductor chip 100 may be used as an upper channel pad, and may be connected to the chip-pad 420 of the upper memory chips UMC through the first wire 310, the first substrate pad 210, the third substrate pad 230, and a second wire 320a to exchange signals with the upper memory chips UMC. The first substrate pad 210 and the third substrate pad 230 may be connected to each other through the substrate wiring of the package substrate 200.

The first signal pad 120S1 may be included in the left chip-pad 120L as shown in FIG. 1 and may be located on a left edge of the semiconductor chip 100 in the x direction. However, in some embodiments, the first signal pad 120S1 may be included in the right chip-pad 120R and may be located on a right edge of the semiconductor chip 100 in the x direction. When the first signal pad 120S1 is located on a right edge, the first substrate pad 210 and the third substrate pad 230 connected to the first signal pad 120S1 may be integrated into one and may be connected to each other without the substrate wiring.

As the first signal pad 120S1 of the first chip-pad 120 of the semiconductor chip 100 is used as an upper channel pad, the second chip-pad 130 may not be used. That is, a wire may not be connected to the second chip-pad 130. According to various wiring connection structures of FIGS. 3A to 4C, the second chip-pad 130 may be deactivated or may be maintained in an active state.

Because the semiconductor packages 1000 and 1000a of the present disclosure selectively use the second chip-pad 130 and the first signal pad 120S1 of the first chip-pad 120 as an upper channel pad based on a chip-pad arrangement structure of the semiconductor chip 100, a freer wire connection structure may be implemented between the semiconductor chip 100 and the chip stacked structure CSS. Alternatively or additionally, as in a structure of the semiconductor package 1000a of FIG. 5B, even when the second wire 320a used for an upper channel is connected to the package substrate 200, the second chip-pad 130 at a central portion of the semiconductor chip 100 may not necessarily need to be used. Accordingly, as described with reference to FIGS. 2A to 2C, the size of the semiconductor package 1000a may not greatly increase compared to the semiconductor package 1000 of FIG. 5A.

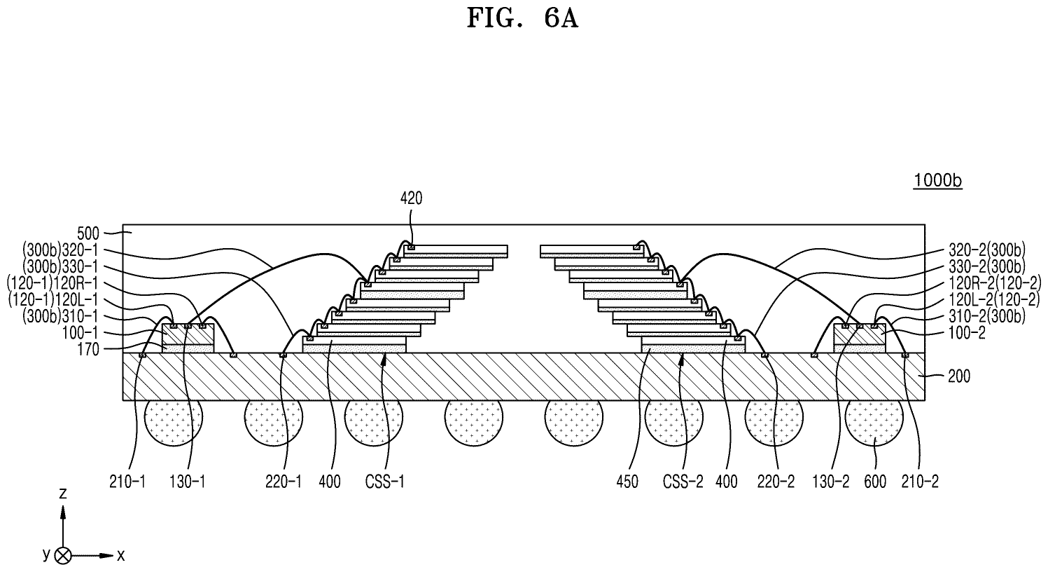

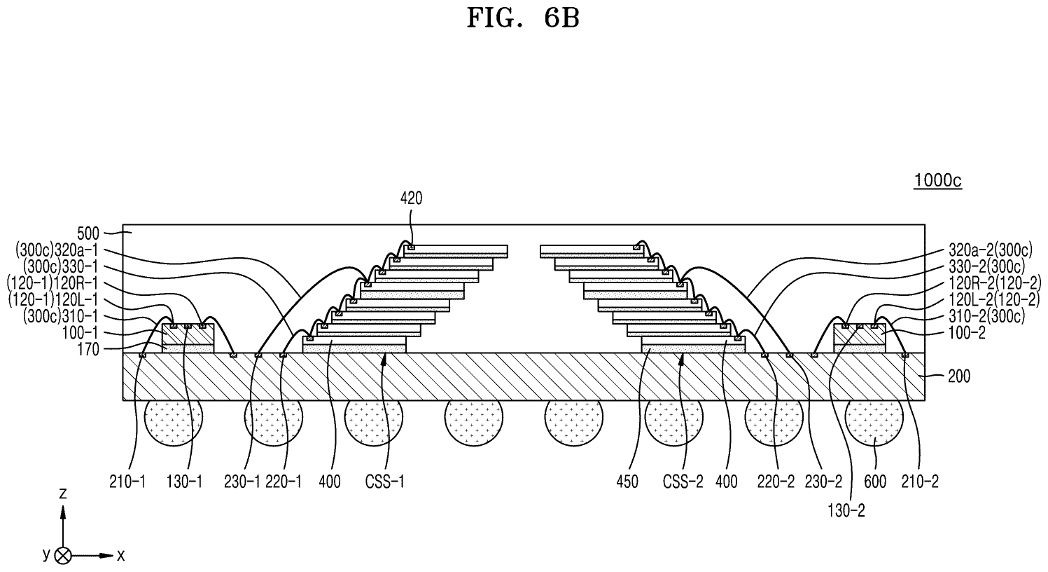

FIGS. 6A and 6B are cross-sectional views illustrating a semiconductor package including the semiconductor chip of FIG. 1, according to embodiments. FIGS. 6A and 6B are described together with FIGS. 1, 5A, and 5B. Repeated descriptions of the elements described above with reference to FIGS. 1 to 5B may be omitted for the sake of brevity.

Referring to FIG. 6A, a semiconductor package 1000b of the present disclosure may have a structure in which two semiconductor packages of FIG. 5A are arranged along the x direction. That is, the semiconductor package 1000b of the present disclosure may include a first semiconductor chip 100-1, a second semiconductor chip 100-2, the package substrate 200, a wire 300b, a first chip stacked structure CSS-1, a second chip stacked structure CSS-2, the sealing member 500, and the external connection terminal 600.

The first semiconductor chip 100-1, a left half portion of the package substrate 200 and the wire 300b, the first chip stacked structure CSS-1, and a left half portion of the sealing member 500 and the external connection terminal 600 may be substantially similar and/or the same as those in the semiconductor package 1000 of FIG. 5A. Alternatively or additionally, the second semiconductor chip 100-2, a right half portion of the package substrate 200 and the wire 300b, the second chip stacked structure CSS-2, and a right half portion of the sealing member 500 and the external connection terminal 600 may be substantially similar and/or the same as the semiconductor package 1000 of FIG. 5A when rotated by 180° in the z axis.

Each of the first semiconductor chip 100-1 and the second semiconductor chip 100-2 may have a dual chip-pad structure, and/or may be substantially similar or the same the same as the first semiconductor chip 100 of FIG. 1. For reference, in FIG. 6A, the second semiconductor chip 100-2 may be rotated by 180° in the z axis with respect to the first semiconductor chip 100-1 and may be located on the package substrate 200. Alternatively or additionally, the memory chips 400 of the second chip stacked structure CSS-2 may be rotated by 180° in the z axis with respect to the memory chips 400 of the first chap stacked structure CSS-1 and may be stacked and located on the package substrate 200.

Referring to FIG. 6B, a semiconductor package 1000c of the present disclosure may have a structure in which two semiconductor packages 1000a of FIG. 5B are arranged along the x axis. That is, the semiconductor package 1000c of the present disclosure may include the first semiconductor chip 100-1, the second semiconductor chip 100-2, the package substrate 200, a wire 300c, the first chip stacked structure CSS-1, the second chip stacked structure CSS-2, the sealing member 500, and the external connection terminal 600.

The first semiconductor chip 100-1, a left half portion of the package substrate 200 and the wire 300c, the first chip stacked structure CSS-1, and a left portion of the sealing member 500 and the external connection terminal 600 may be substantially similar and/or the same as those in the semiconductor package 1000a of FIG. 5B. Alternatively or additionally, the second semiconductor chip 100-2, a right half portion of the package substrate 200 and the wire 300c, the second chip stacked structure CSS-2, and a right half portion of the sealing member 500 and the external connection terminal 600 may be substantially similar and/or the same as those in the semiconductor package 1000a of FIG. 5B when rotated by 180° in the z axis.

Each of the first semiconductor chip 100-1 and the second semiconductor chip 100-2 may have a dual chip-pad structure and may be substantially similar and/or the same as the semiconductor chip 100 of FIG. 1. Alternatively or additionally, in FIG. 6B, the second semiconductor chip 100-2 may be rotated by 180° in the z axis with respect to the first semiconductor chip 100-1 and may be located on the package substrate 200. In an embodiment, the memory chips 400 of the second chip stacked structure CSS-2 may be rotated by 180° in the z axis with respect to the memory chips 400 of the first chip stacked structure CSS-1 and may be stacked and located on the package substrate 200.

Because the semiconductor packages 1000b and 1000c of the present disclosure selectively use the second chip-pad 130 and the first signal pad 120S1 of the first chip-pad 120 as an upper channel pad based on a chip-pad arrangement structure of the first and second semiconductor chips 100-1 and 100-2, a freer wire connection structure may be implemented between the first and second semiconductor chips 100-1 and 100-2 and the first and second chip stacked structures CSS-1 and CSS-2. Alternatively or additionally, as in a structure of the semiconductor package 1000c of FIG. 6B, even when second wires 320a-1 and 320a-2 used for an upper channel are connected to the package substrate 200, second chip-pads 130-1 and 130-2 at central portions of the first and second semiconductor chips 100-1 and 100-2 may not necessarily need to be used. Accordingly, the size of the semiconductor package 1000c of FIG. 6B may not greatly increase compared to the semiconductor package 1000b of FIG. 6A.

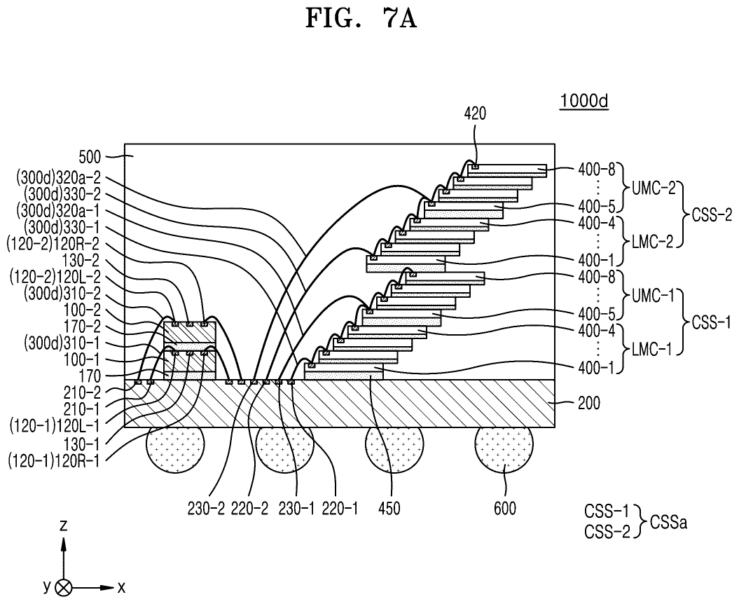

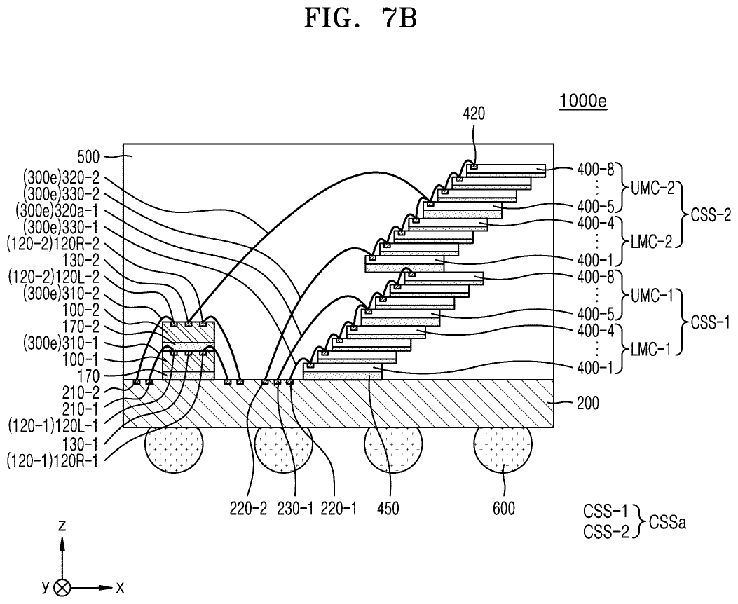

FIGS. 7A and 7B are cross-sectional views illustrating a semiconductor package including the semiconductor chip of FIG. 1, according to embodiments. FIGS. 7A and 7B are described together with FIGS. 1, 5A, and 5B. Repeated descriptions of elements described above with reference to FIGS. 1-6B may be omitted for the sake of brevity.

Referring to FIG. 7A, a semiconductor package 1000d of the present disclosure may have a structure in which two semiconductor chips 100 and two chip stacked structures CSS of the semiconductor package 1000a of FIG. 5B are stacked. That is, the semiconductor package 1000d of the present disclosure may include the first semiconductor chip 100-1, the second semiconductor chip 100-2, the package substrate 200, a wire 300d, the first chip stacked structure CSS-1, the second chip stacked structure CSS-2, the sealing member 500, and the external connection terminal 600. The package substrate 200, the sealing member 500, and the external connection terminal 600 may be substantially similar and/or the same as those in the semiconductor package 1000 of FIG. 5A.

Each of the first semiconductor chip 100-1 and the second semiconductor chip 100-2 may have a dual chip-pad structure and may be substantially similar and/or the same as the semiconductor chip 100 of FIG. 1. Alternatively or additionally, the second semiconductor chip 100-2 may be stacked on the first semiconductor chip 100-1 through an adhesive layer 170.

Each of the first chip stacked structure CSS-1 and the second chip stacked structure CSS-2 may be substantially similar and/or the same as the chip stacked structure CSS of FIG. 5A. Accordingly, the first chip stacked structure CSS-1 may include a lower memory chip LMC-1 and an upper memory chip UMC-1, and the second chip stacked structure CSS-2 may include a lower memory chip LMC-2 and an upper memory chip UMC-2. Alternatively or additionally, the second chip stacked structure CSS-2 may be stacked on the first chip stacked structure CSS-1 through the adhesive layer 450 to constitute an overall chip stacked structure CSSa together with the first chip stacked structure CSS-1.

A connection relationship through the wire 300d between the first and second semiconductor chips 100-1 and 100-2, the memory chips 400 of the first and second chip stacked structures CSS-1 and CSS-2, and the package substrate 200 may be described as follows.

A connection relationship through the wire 300d between the second signal pads 120S2R and 120S2L of a first chip-pad 120-1 and a third chip-pad 140-1 of the first semiconductor chip 100-1 and the first chip stacked structure CSS-1 may be substantially similar and/or the same as that in the semiconductor package 1000a of FIG. 5B. A first substrate pad 210-1, a second substrate pad 220-1, a third substrate pad 230-1, a first wire 310-1, the second wire 320a-1, and a third wire 330-1 may respectively correspond to the first substrate pad 210, the second substrate pad 220, the third substrate pad 230, the first wire 310, the second wire 320a, and the third wire 330 in the semiconductor package 1000a of FIG. 5B. Because the second semiconductor chip 100-2 is stacked on the first semiconductor chip 100-1 through the adhesive layer 170, at least a part of the first wire 310-1 connected to the first semiconductor chip 100-1 may be covered by the adhesive layer 170.

A connection relationship through the wire 300d between the second signal pads 120S2R and 120S2L of a first chip-pad 120-2 and a third chip-pad 140-2 of the second semiconductor chip 100-2 and the second chip stacked structure CSS-2 may be substantially similar and/or the same as that in the semiconductor package 1000a of FIG. 5B. A first substrate pad 210-2, a second substrate pad 220-2, a third substrate pad 230-2, a first wire 310-2, the second wire 320a-2, and a third wire 330-2 may respectively correspond to the first substrate pad 210, the second substrate pad 220, the third substrate pad 230, the first wire 310, the second wire 320a, and the third wire 330 in the semiconductor package 1000a of FIG. 5B.

In the semiconductor package 1000d of the present disclosure, the first signal pad 120S1 of the first chip-pads 120-1 and 120-2 of the first and second semiconductor chips 100-1 and 100-2 may be used as an upper channel pad, and may be connected to the chip-pad 420 of the upper memory chips UMC-1 and UMC-2 of the first and second chip stacked structures CSS-1 and CSS-2 through the first wires 310-1 and 310-2, the first substrate pads 210-1 and 210-2, the third substrate pads 230-1 and 230-2, and the second wires 320a-1 and 320a-2 to exchange signals with the upper memory chips UMC-1 and UMC-2.

As the first signal pad 120S1 of the first chip-pads 120-1 and 120-2 of the first and second semiconductor chips 100-1 and 100-2 is used as an upper channel pad, the second chip-pads 130-1 and 130-2 may not be used. That is, a wire may not be connected to the second chip-pads 130-1 and 130-2. According to various wiring connection structures of FIGS. 3A to 4C, the second chip-pads 130-1 and 130-2 may be deactivated or may be maintained in an active state.

Referring to FIG. 7B, a semiconductor package 1000e of the present disclosure may have a structure in which the semiconductor chip 100 and the chip stacked structure CSS of the semiconductor package 1000 of FIG. 5A may be stacked on the semiconductor chip 100 and the chip stacked structure CSS of the semiconductor package 1000a of FIG. 5B. That is, the semiconductor package 1000e of the present disclosure may include the first semiconductor chip 100-1, the second semiconductor chip 100-2, the package substrate 200, a wire 300e, the first chip stacked structure CSS-1, the second chip stacked structure CSS-2, the sealing member 500, and the external connection terminal 600. The package substrate 200, the sealing member 500, and the external connection terminal 600 may be substantially similar and/or the same as those in the semiconductor package 1000 of FIG. 5A.

Each of the first semiconductor chip 100-1 and the second semiconductor chip 100-2 may have a dual chip-pad structure and/or may be substantially similar and/or the same as the semiconductor chip 100 of FIG. 1. Alternatively or additionally, the second semiconductor chip 100-2 may be stacked on the first semiconductor chip 100-1 through the adhesive layer 170.

Each of the first chip stacked structure CSS-1 and the second chip stacked structure CSS-2 may be substantially similar and/or the same as the chip stacked structure CSS of FIG. 5A. Accordingly, the first chip stacked structure CSS-1 may include the lower memory chip LMC-1 and the upper memory chip UMC-1, and the second chip stacked structure CSS-2 may include the lower memory chip LMC-2 and the upper memory chip UMC-2. Alternatively or additionally, the second chip stacked structure CSS-2 may be stacked on the first chip stacked structure CSS-1 through the adhesive layer 450 to constitute the overall chip stacked structure CSSa together with the first chip stacked structure CSS-1.

A connection relationship through the wire 300e between the first and second semiconductor chips 100-1 and 100-2, the memory chips 400 of the first and second chip stacked structures CSS-1 and CSS-2, and the package substrate 200 may be described as follows.

A connection relationship through the wire 300e between the second signal pads 120S2R and 120S2L of the first chip-pad 120-1 and the third chip-pad 140-1 of the first semiconductor chip 100-1 and the first chip stacked structure CSS-1 may be substantially similar and/or the same as that in the semiconductor package 1000a of FIG. 5B. The first substrate pad 210-1, the second substrate pad 220-1, the third substrate pad 230-1, the first wire 310-1, the second wire 320a-1, and the third wire 330-1 may respectively correspond to the first substrate pad 210, the second substrate pad 220, the third substrate pad 230, the first wire 310, the second wire 320a, and the third wire 330 in the semiconductor package 1000a of FIG. 5B. Because the second semiconductor chip 100-2 is stacked on the first semiconductor chip 100-1 through the adhesive layer 170, at least a part of the first wire 310-1 connected to the first semiconductor chip 100-1 may be covered by the adhesive layer 170.

A connection relationship through the wire 300e between the second signal pads 120S2R and 120S2L of the first chip-pad 120-2 and the third chip-pad 140-2 of the second semiconductor chip 100-2 and the second chip stacked structure CSS-2 may be substantially similar and/or the same as that in the semiconductor package 1000 of FIG. 5A. The first substrate pad 210-2, the second substrate pad 220-2, the third substrate pad 230-2, the first wire 310-2, a second wire 320-2, and the third wire 330-2 may respectively correspond to the first substrate pad 210, the second substrate pad 220, the third substrate pad 230, the first wire 310, the second wire 320, and the third wire 330 in the semiconductor package 1000 of FIG. 5A.

In a semiconductor package 1000e of the present disclosure, the first signal pad 120S1 of the first chip-pad 120-1 of the first semiconductor chip 100-1 may be used as an upper channel pad, and the second chip-pad 130-2 of the second semiconductor chip 100-2 may be used as an upper channel pad. Alternatively or additionally, the first signal pad 120S-1 of the first semiconductor chip 100-1 and the second chip-pad 130-2 of the second semiconductor chip 100-2 may be connected to the chip-pad 420 of the upper memory chips UMC-1 and UMC-2 of the first and second chip stacked structures CSS-1 and CSS-2 through the first wires 310-1 and 310-2, the first substrate pads 210-1 and 210-2, the third substrate pad 230-1, and the second wires 320a-1 and 320-2 to exchange signals with the upper memory chips UMC-1 and UMC-2.

As the first signal pad 120S1 of the first chip-pad 120-1 is used as an upper channel pad in the first semiconductor chip 100-1, the second chip-pad 130-1 may not be used. That is, a wire may not be connected to the second chip-pad 130-1. According to various wiring connection structures of FIGS. 3A to 4C, the second chip-pad 130-1 may be deactivated or may be maintained in an active state.

In the case of the second semiconductor chip 100-2, because the second chip-pad 130-2 is used as an upper channel pad, the first signal pad 120S1 of the first chip-pad 120-2 may not be used. That is, a wire may not be connected to the first signal pad 120S1 of the first chip-pad 120-2. According to various wiring connection structures of FIGS. 3A to 4C, the first signal pad 120S1 of the first chip-pad 120-2 may be deactivated or may be maintained in an active state.

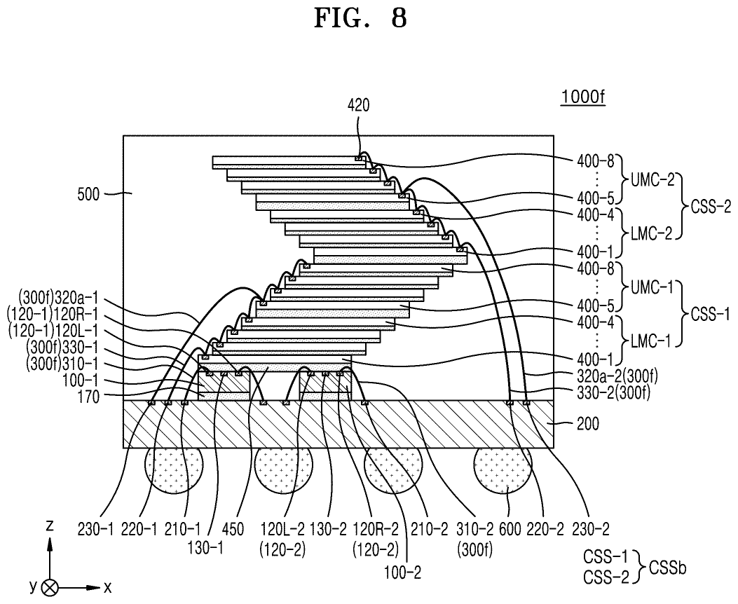

FIG. 8 is a cross-sectional view illustrating a semiconductor package including the semiconductor chip of FIG. 1, according to an embodiment. FIG. 8 is described together with FIG. 1. Repeated descriptions of elements described above with reference to FIGS. 1-7B may be omitted for the sake of brevity.

Referring to FIG. 8, a semiconductor package 1000f of the present disclosure may include two semiconductor chips 100-1 and 100-2 and two chip stacked structures CSS-1 and CSS-2 like the semiconductor package 1000d or 1000e of FIG. 7A or 7B. However, an arrangement structure on the package substrate 200 may be different from the semiconductor package 1000d or 1000e of FIG. 7A or 7B. That is, the semiconductor package 1000f of the present disclosure may include the first semiconductor chip 100-1, the second semiconductor chip 100-2, the package substrate 200, a wire 300f, the first chip stacked structure CSS-1, the second chip stacked structure CSS-2, the sealing member 500, and the external connection terminal 600. The package substrate 200, the sealing member 500, and the external connection terminal 600 may include and/or may be similar in many respects to those in the semiconductor package 1000 of FIG. 5A.

Each of the first semiconductor chip 100-1 and the second semiconductor chip 100-2 may have a dual chip-pad structure and may be substantially similar and/or the same as the semiconductor chip 100 of FIG. 1. The second semiconductor chip 100-2 may be spaced apart from the first semiconductor chip 100-1 in the x direction and may be stacked on the package substrate 200 through the adhesive layer 170.

Each of the first chip stacked structure CSS-1 and the second chip stacked structure CSS-2 may be substantially similar and/or the same as the chip stacked structure CSS of FIG. 5A. Accordingly, the first chip stacked structure CSS-1 may include the lower memory chip LMC-1 and the upper memory chip UMC-1, and the second chip stacked structure CSS-2 may include the lower memory chip LMC-2 and the upper memory chip UMC-2. The second stacked structure CSS-2 may be stacked on the first chip stacked structure CSS-1 through the adhesive layer 450 to constitute an overall chip stacked structure CSSb together with the first chip stacked structure CSS-1. However, the overall chip stacked structure CSSb may be different from the overall chip stacked structure CSSa of the semiconductor package 1000d or 1000e of FIG. 7A or 7B.

That is, the first chip stacked structure CSS-1 may be substantially similar and/or the same as the first chip stacked structure CSS-1 of the semiconductor package 1000d or 1000e of FIG. 7A or 7B. However, the first chip stacked structure CSS-1 may not be stacked on the package substrate 200 but may be stacked on the first semiconductor chip 100-1 and the second semiconductor chip 100-2 through the adhesive layer 450. The second chip stacked structure CSS-2 may have a stepwise structure in a direction opposite to that of the second chip stacked structure CSS-2 of the semiconductor package 1000d or 1000e of FIG. 7A or 7B. That is, the second chip stacked structure CSS-2 may have a stepwise structure in which positions of the memory chips 400 increase upward and to a left side in the x direction. As used herein, a structure in which memory chips are stacked using two or more semiconductor chips as a support may be referred to as a dolmen structure. Accordingly, in the semiconductor package 1000f of the present disclosure, the first chip stacked structure CSS-1 or the overall chip stacked structure CSSb may have a dolmen structure.

A connection relationship through the wire 300f between the first and second semiconductor chips 100-1 and 100-2, the memory chips 400 of the first and second chip stacked structures CSS-1 and CSS-2, and the package substrate 200 may be described as follows.

A connection relationship through the wire 300f between the second signal pads 120S2R and 120S2L of the first chip-pad 120-1 and the third chip-pad 140-1 of the first semiconductor chip 100-1 and the first chip stacked structure CSS-1 may be substantially similar and/or the same as that in the semiconductor package 1000a of FIG. 5B. The first substrate pad 210-1, the second substrate pad 220-1, the third substrate pad 230-1, the first wire 310-1, the second wire 320a-1, and the third wire 330-1 may respectively correspond to the first substrate pad 210, the second substrate pad 220, the third substrate pad 230, the first wire 310, the second wire 320a, and the third wire 330 in the semiconductor package 1000a of FIG. 5B. However, in the semiconductor package 1000a of FIG. 5B, as the semiconductor chip 100 is located on a left side adjacent to the chip stacked structure CSS in the x direction, the first substrate pad 210 may be located on a left side of the second substrate pad 220 and the third substrate pad 230 in the x direction. Alternatively, in the semiconductor package 1000f of the present disclosure, as the first semiconductor chip 100-1 is located under the first chip stacked structure CSS-1, the first substrate pad 210-1 may be located on a right side of the second substrate pad 220-1 and the third substrate pad 230-1 in the x direction.

A connection relationship through the wire 300f between the second signal pads 120S2R and 120S2L of the first chip-pad 120-2 and the third chip-pad 140-2 of the second semiconductor chip 100-2 and the second chip stacked structure CSS-2 may be substantially similar and/or the same as that in the semiconductor package 1000a of FIG. 5B. The first substrate pad 210-2, the second substrate pad 220-2, the third substrate pad 230-2, the first wire 310-2, the second wire 320a-2, and the third wire 330-2 may respectively correspond to the first substrate pad 210, the second substrate pad 220, the third substrate pad 230, the first wire 310, the second wire 320a, and the third wire 330 in the semiconductor package 1000a of FIG. 5B. However, in the semiconductor package 1000f of the present disclosure, as the second semiconductor chip 100-2 is located under the second chip stacked structure CSS-2 and the second chip stacked structure CSS-2 has a stepwise structure to a left side, the second wire 320a-2 and the third wire 330-2 may be located on a right side of the second chip stacked structure CSS-2. Alternatively or additionally, the second substrate pad 220-2 and the third substrate pad 230-2 may be located on a right side of the second chip stacked structure CSS-2, and the first substrate pad 210-2 may be located on a left side of the second substrate pad 220-2 and the third substrate pad 230-2 in the x direction.

In the semiconductor package 1000f of the present disclosure, the first signal pad 120S1 of the first chip-pads 120-1 and 120-2 of the first and second semiconductor chips 100-1 and 100-2 may be an upper channel pad, and may be connected to the chip-pad 420 of the upper memory chips UMC-1 and UMC-2 of the first and second chip stacked structures CSS-1 and CSS-2 through the first wires 310-1 and 310-2, the first substrate pads 210-1 and 210-2, the third substrate pads 230-1 and 230-2, and the second wires 320a-1 and 320a-2 to exchange signals with the upper memory chips UMC-1 and UMC-2.

As the first signal pad 120S1 of the first chip-pads 120-1 and 120-2 of the first and second semiconductor chips 100-1 and 100-2 is used as an upper channel pad, the second chip-pads 130-1 and 130-2 may not be used. That is, a wire may not be connected to the second chip-pads 130-1 and 130-2. According to various wiring connection structures of FIGS. 3A to 4C, the second chip-pads 130-1 and 130-2 may be deactivated or may be maintained in an active state.

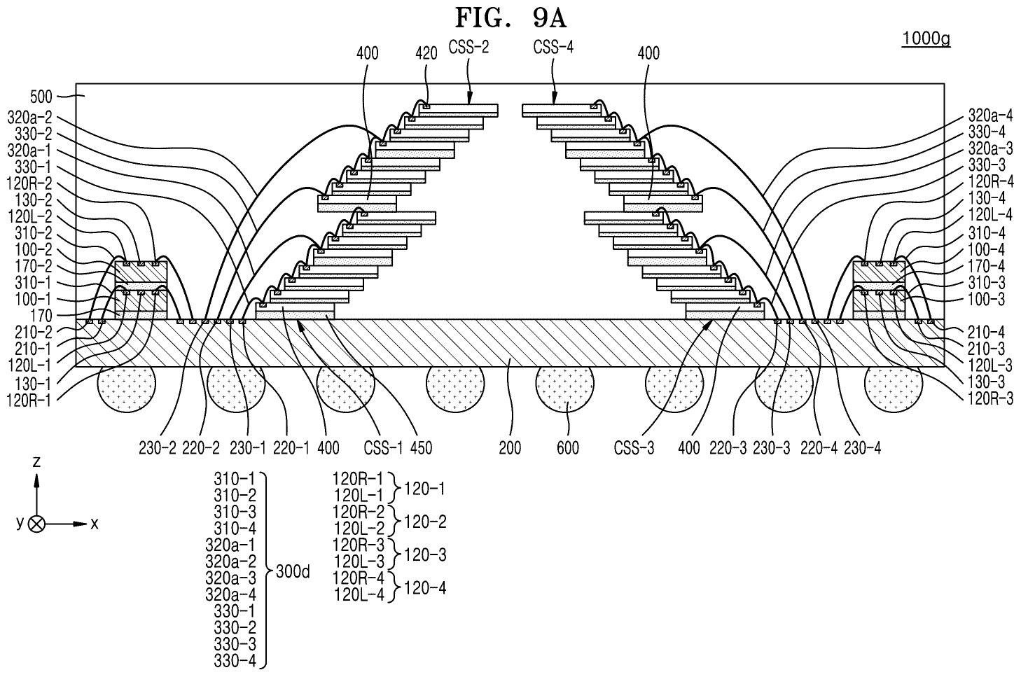

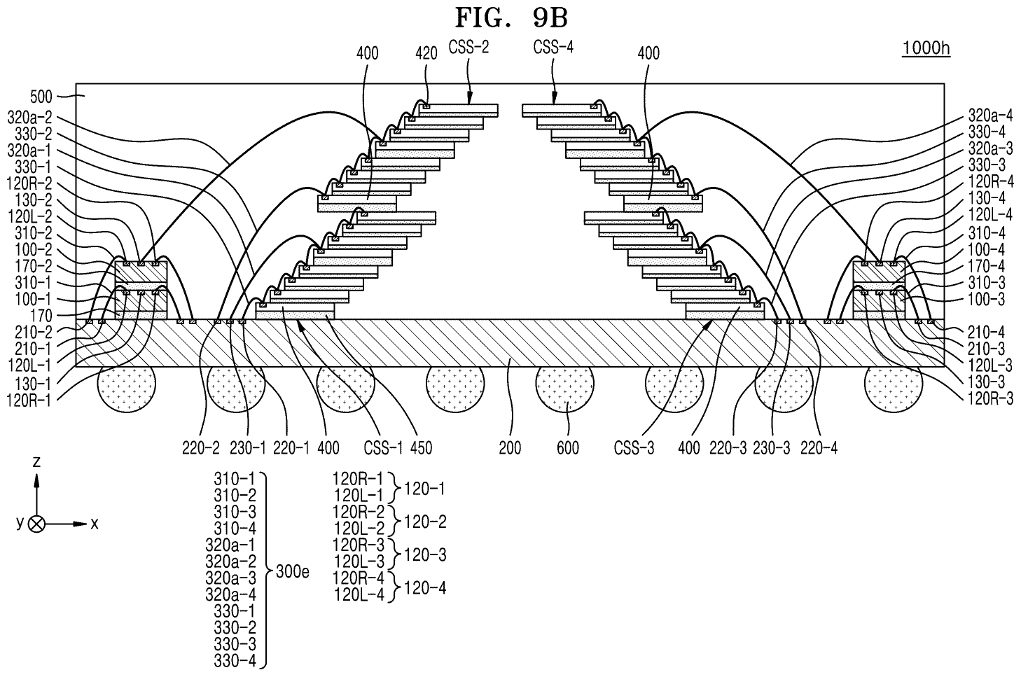

FIGS. 9A and 9B are cross-sectional views illustrating a semiconductor package including the semiconductor chip of FIG. 1, according to embodiments. FIGS. 9A and 9B may be described together with FIGS. 1, 7A, and 7B. Repeated descriptions of the elements described above with reference to FIGS. 1-8 may be omitted for the sake of brevity.

Referring to FIG. 9A, a semiconductor package 1000g of the present disclosure may have a structure in which two semiconductor packages 1000d of FIG. 7A are arranged along the x direction. That is, the semiconductor package 1000g of the present disclosure may include semiconductor chips (e.g., a first semiconductor chip 100-1, a second semiconductor chip 100-2, a third semiconductor chip 100-3, and a fourth semiconductor chip 100-4), the package substrate 200, the wire 300d, chip stacked structures (e.g., a first chip stacked structure CSS-1, a second chip stacked structure CSS-2, a third chip stacked structure CSS-3, and a fourth chip stacked structure CSS-4), the sealing member 500, and the external connection terminal 600. The package substrate 200, the sealing member 500, and the external connection terminal 600 may include and/or may be similar in many respects to those in the semiconductor package 1000 of FIG. 5A.

The first and second semiconductor chips 100-1 and 100-2, a left half portion of the package substrate 200 and the wire 300d, the first and second chip stacked structures CSS-1 and CSS-2, and a left half portion of the sealing member 500 and the external connection terminal 600 may be substantially similar and/or the same as those in the semiconductor package 1000d of FIG. 7A. Alternatively or additionally, the third and fourth semiconductor chips 100-3 and 100-4, a right half portion of the package substrate 200 and the wire 300d, the third and fourth chip stacked structures CSS-3 and CSS-4, and a right half portion of the sealing member 500 and the external connection terminal 600 may be substantially similar and/or the same as those in the semiconductor package 1000d of FIG. 7A when rotated by 180° in the z axis.

Each of the first to fourth semiconductor chips 100-1 to 100-4 may have a dual chip-pad structure and may be substantially similar and/or the same as the semiconductor chip 100 of FIG. 1. Referring to FIG. 9A, a stacked structure of the third and fourth semiconductor chips 100-3 and 100-4 may be rotated by 180° in the z axis with respect to a stacked structure of the first and second semiconductor chips 100-1 and 100-2 and may be located on the package substrate 200. The memory chips 400 of the third and fourth chip stacked structures CSS-3 and CSS-4 may be rotated by 180° in the z axis with respect to the memory chips 400 of the first and second chip stacked structures CSS-1 and CSS-2 and may be stacked and located on the package substrate 200.

Referring to FIG. 9B, a semiconductor package 1000h of the present disclosure may have a structure in which two semiconductor packages 1000e of FIG. 7B may be arranged along the x direction. That is, the semiconductor package 1000h of the present disclosure may include the first to fourth semiconductor chips 100-1 to 100-4, the package substrate 200, the wire 300e, the first to fourth chip stacked structures CSS-1 to CSS-4, the sealing member 500, and the external connection terminal 600. The package substrate 200, the sealing member 500, and the external connection terminal 600 may include and/or may be similar in many respects to those in the semiconductor package 1000 of FIG. 5A.

The first and second semiconductor chips 100-1 and 100-2, a left half portion of the package substrate 200 and the wire 300e, the first and second chip stacked structures CSS-1 and CSS-2, and a left half portion of the sealing member 500 and the external connection terminal 600 may be substantially similar and/or the same as those in the semiconductor package 1000e of FIG. 7B. Alternatively or additionally, the third and fourth semiconductor chips 100-3 and 100-4, a right half portion of the package substrate 200 and the wire 300e, the third and fourth chip stacked structures CSS-3 and CSS-4, and a right half portion of the sealing member 500 and the external connection terminal 600 may be substantially similar and/or the same as those in the semiconductor package 1000e of FIG. 7B when rotated by 180° in the z axis.

Each of the first to fourth semiconductor chips 100-1 to 100-4 may have a dual chip-pad structure and may be substantially similar and/or the same as the semiconductor chip 100 of FIG. 1. Referring to FIG. 9B, a stacked structure of the third and fourth semiconductor chips 100-3 and 100-4 may be rotated by 180° in the z axis with respect to a stacked structure of the first and second semiconductor chips 100-1 and 100-2 and may be located on the package substrate 200. Alternatively or additionally, the memory chips 400 of the third and fourth chip stacked structures CSS-3 and CSS-4 may be rotated by 180° in the z axis with respect to the memory chips 400 of the first and second chip stacked structures CSS-1 and CSS-2 and may be stacked and located on the package substrate 200.

While the present disclosure has been particularly shown and described with reference to embodiments thereof, it is to be understood that various changes in form and details may be made therein without departing from the spirit and scope of the following claims.

What is claimed is:

1. A semiconductor chip with a dual chip-pad structure, the semiconductor chip comprising:
a chip body;
a first chip-pad disposed on a first edge of a top surface of the chip body and a second edge of the top surface of the chip body, the second edge of the top surface being opposite to the first edge of the top surface in a first direction, the first chip-pad being disposed along a second direction perpendicular to the first direction; and
a second chip-pad disposed along the second direction at a central portion of the top surface between the first edge of the top surface of the chip body and the second edge of the top surface of the chip body in the first direction,
wherein the first chip-pad comprises a first signal pad coupled with the second chip-pad.

2. The semiconductor chip of claim 1, wherein the second chip-pad is coupled with the first signal pad through at least one of a redistribution layer (RDL) of the chip body or an internal wiring of a multi-wiring layer of the chip body.

3. The semiconductor chip of claim 1, wherein the semiconductor chip comprises a semiconductor package, and
wherein the second chip-pad and the first signal pad are selectively coupled with memory chips of the semiconductor package.

4. The semiconductor chip of claim 3, wherein at least one of the second chip-pad or the first signal pad, which is not coupled with the memory chips of the semiconductor package, is configured to be deactivated through a switching element.

5. The semiconductor chip of claim 1, wherein the semiconductor chip comprises a buffer chip disposed on a package substrate of a semiconductor package,
wherein the semiconductor package comprises a chip stacked structure disposed on the package substrate adjacent to the semiconductor chip and comprising a plurality of memory chips stacked therein,
wherein the first chip-pad further comprises a second signal pad,
wherein the second chip-pad and the first signal pad are selectively coupled with upper memory chips of the plurality of memory chips and disposed at a first position in the chip stacked structure,
wherein the second signal pad is coupled with lower memory chips of the plurality of memory chips and disposed at a second position in the chip stacked structure, and
wherein the second position is lower than the first position.

6. A semiconductor package, comprising:
a package substrate;
a first semiconductor chip disposed on the package substrate, having a first dual chip-pad structure, and comprising a chip body, a first chip-pad, and a second chip-pad disposed on a top surface of the chip body; and
a first chip stacked structure disposed on the package substrate adjacent to the first semiconductor chip in a first direction and comprising a first plurality of memory chips stacked therein,
wherein the first chip-pad is disposed on a first edge of the top surface of the chip body and a second edge of the top surface of the chip body, the second edge of the top surface being opposite to the first edge of the top surface in the first direction, and the first chip-pad being disposed along a second direction perpendicular to the first direction,
wherein the second chip-pad is disposed along the second direction at a central portion of the top surface between the first edge of the top surface of the chip body and the second edge of the top surface of the chip body in the first direction, and
wherein the first chip-pad comprises a first signal pad coupled with the second chip-pad.

7. The semiconductor package of claim 6, wherein the first chip-pad further comprises a second signal pad,
wherein the second chip-pad and the first signal pad are selectively coupled with first memory chips of the first plurality of memory chips disposed at a first position in the first chip stacked structure,
wherein the second signal pad is coupled with second memory chips of the first plurality of memory chips and disposed at a second position in the first chip stacked structure, and wherein the second position is lower than the first position.

8. The semiconductor package of claim 6, further comprising:
a second chip stacked structure on the package substrate adjacent to the first chip stacked structure in the first direction and comprising a second plurality of memory chips stacked therein; and
a second semiconductor chip disposed on the package substrate adjacent to the second chip stacked structure in the first direction and having a second dual chip-pad structure same as the first dual chip-pad structure of the first semiconductor chip,
wherein the first semiconductor chip is coupled with the first plurality of memory chips of the first chip stacked structure, and
wherein the second semiconductor chip is coupled with the second plurality of memory chips of the second chip stacked structure.

9. The semiconductor package of claim 6, further comprising:
a second semiconductor chip stacked on the first semiconductor chip and having a second dual chip-pad structure same as the first dual chip-pad structure of the first semiconductor chip,
wherein the first chip stacked structure comprises a lower chip stacked structure and an upper chip stacked structure,
wherein the first semiconductor chip is coupled with lower memory chips of the lower chip stacked structure, and
wherein the second semiconductor chip is coupled with upper memory chips of the upper chip stacked structure.

10. The semiconductor package of claim 9, wherein the first chip-pad of the first semiconductor chip further comprises a second signal pad,
wherein the second semiconductor chip further comprises a second signal pad,
wherein the first signal pad of the first semiconductor chip is coupled with the upper memory chips at a first position in the lower chip stacked structure,
wherein the second signal pad of the first semiconductor chip is coupled with the lower memory chips at a second position in the lower chip stacked structure,
wherein the second position is lower than the first position,
wherein the second chip-pad and the first signal pad of the second semiconductor chip are selectively coupled with the upper memory chips at a third position in the upper chip stacked structure,
wherein the second signal pad of the second semiconductor chip is coupled with the lower memory chips at a fourth position in the upper chip stacked structure, and
wherein the fourth position is lower than the third position.

11. The semiconductor package of claim 9, wherein the first semiconductor chip is coupled with a first substrate pad of the package substrate through a first wire,
wherein the lower memory chips of the lower chip stacked structure are coupled with a second substrate pad of the package substrate through a second wire,
wherein the second semiconductor chip is coupled with a third substrate pad of the package substrate through a third wire,
wherein the upper memory chips of the upper chip stacked structure are coupled with a fourth substrate pad of the package substrate through a fourth wire,
wherein the first substrate pad is coupled with the second substrate pad through a substrate wiring of the package substrate,
wherein the third substrate pad is coupled with the fourth substrate pad through the substrate wiring of the package substrate, and
wherein at least a part of the first wire is covered by an adhesive layer between the first semiconductor chip and the second semiconductor chip.

12. The semiconductor package of claim 6, further comprising:
a second semiconductor chip stacked on the first semiconductor chip and having a second dual chip-pad structure same as the first dual chip-pad structure of the first semiconductor chip;
a second chip stacked structure on the package substrate adjacent to the first chip stacked structure and comprising a second plurality of memory chips stacked therein;
a third semiconductor chip on the package substrate adjacent to the second chip stacked structure in the first direction and having a third dual chip-pad structure same as the first dual chip-pad structure of the first semiconductor chip; and
a fourth semiconductor chip stacked on the third semiconductor chip and having a fourth dual chip-pad structure same as the first dual chip-pad structure of the first semiconductor chip,
wherein the first semiconductor chip and the second semiconductor chip are coupled with the first plurality of memory chips of the first chip stacked structure, and
wherein the third semiconductor chip and the fourth semiconductor chip are coupled with the second plurality of memory chips of the second chip stacked structure.

13. The semiconductor package of claim 12, wherein each of the first chip stacked structure and the second chip stacked structure has a lower chip stacked structure and an upper chip stacked structure,
wherein the first semiconductor chip is coupled with first lower memory chips of the lower chip stacked structure of the first chip stacked structure,
wherein the second semiconductor chip is coupled with first upper memory chips of the upper chip stacked structure of the first chip stacked structure,
wherein the third semiconductor chip is coupled with second lower memory chips of the lower chip stacked structure of the second chip stacked structure; and
wherein the fourth semiconductor chip is coupled with second upper memory chips of the upper chip stacked structure of the second chip stacked structure.

14. The semiconductor package of claim 6, wherein the first semiconductor chip comprises a buffer chip, and
wherein the first plurality of memory chips comprises NAND flash memory chips.

15. The semiconductor package of claim 6, wherein the second chip-pad and the first signal pad are selectively coupled with the first plurality of memory chips of the first chip stacked structure, and
wherein at least one of the second chip-pad or the first signal pad, which is not coupled with the first plurality of memory chips, is configured to be deactivated through a switching element.

16. A semiconductor package, comprising:
a package substrate;
a first semiconductor chip on the package substrate, having a first dual chip-pad structure, and comprising a chip body, a first chip-pad, and a second chip-pad disposed on a top surface of the chip body;
a second semiconductor chip on the package substrate adjacent to the first semiconductor chip in a first direction and having a second dual chip-pad structure same as the first dual chip-pad structure of the first semiconductor chip; and
a chip stacked structure disposed on the first semiconductor chip and the second semiconductor chip and comprising a plurality of memory chips stacked therein,
wherein the first chip-pad of each of the first semiconductor chip and the second semiconductor chip is disposed on a first edge of the top surface of the chip body and a second edge of the top surface of the chip body, the second edge of the top surface being opposite to the first edge of the top surface in the first direction, the first chip-pad being disposed along a second direction perpendicular to the first direction,
wherein the second chip-pad of each of the first semiconductor chip and the second semiconductor chip is disposed along the second direction at a central portion of the top surface between the first edge of the top surface of the chip body and the second edge of the top surface of the chip body in the first direction, and
wherein the first chip-pad of each of the first semiconductor chip and the second semiconductor chip comprises a first signal pad coupled with the second chip-pad.

17. The semiconductor package of claim 16, wherein the chip stacked structure comprises a lower chip stacked structure and an upper chip stacked structure,
wherein the first semiconductor chip is coupled with lower memory chips of the lower chip stacked structure, and
wherein the second semiconductor chip is coupled with upper memory chips of the upper chip stacked structure.

18. The semiconductor package of claim 17, wherein the lower chip stacked structure has a stepwise structure in which positions of the lower memory chips increase upward and to a right side in the first direction, and
wherein the upper chip stacked structure has a stepwise structure in which positions of the upper memory chips increase upward and to a left side in the first direction.

19. The semiconductor package of claim 17, wherein the first chip-pad of each of the first semiconductor chip and the second semiconductor chip further comprises a second signal pad,
wherein the first signal pad of the first semiconductor chip is coupled with the upper memory chips at a first position in the lower chip stacked structure,
wherein the second signal pad of the first semiconductor chip is coupled with the lower memory chips at a second position in the lower chip stacked structure,
wherein the second position is lower than the first position,
wherein the first signal pad of the second semiconductor chip is coupled with the upper memory chips at a third position in the upper chip stacked structure,
wherein the second signal pad of the second semiconductor chip is coupled with the lower memory chips at a fourth position in the upper chip stacked structure, and
wherein the fourth position is lower than the third position.

20. The semiconductor package of claim 17, wherein the first semiconductor chip and the second semiconductor chip are spaced apart from each other in the first direction,
wherein the first semiconductor chip is coupled with a first substrate pad of the package substrate on a first side and a second side of the first semiconductor chip in the first direction through a first wire,
wherein the lower memory chips of the lower chip stacked structure are coupled with a second substrate pad of the package substrate on a left side of the first semiconductor chip in the first direction through a second wire,
wherein the second semiconductor chip is coupled with a third substrate pad of the package substrate on a third side and a fourth side of the second semiconductor chip in the first direction through a third wire,
wherein the upper memory chips of the upper chip stacked structure are coupled with a fourth substrate pad of the package substrate on a right side of the second semiconductor chip in the first direction through a fourth wire, and
wherein at least a part of each of the first wire and the third wire is covered by an adhesive layer between the first semiconductor chip and a lowermost memory chip and between the second semiconductor chip and the lowermost memory chip.
